(19) United States
(12) Patent Application Publication
(10) Pub. No.: US 2008/0073101 A1
(43) Pub. Date: Mar. 27, 2008

(54) WALL OUTLET COVER AND PRONG DEVICE

(76) Inventor: Basel Mason, White Plains, NY (US)

Correspondence Address: HOWARD M COHN;PATENT ATTORNEY LLC, 21625 CHAGRIN BLVD #220, CLEVELAND, OH, 44122, US

(21) Appl. No.: 11/756,724

(22) Filed: Jun. 1, 2007

Related U.S. Application Data
(60) Provisional application No. 60/826,473, filed on Sep. 21, 2006.

(51) Int. Cl. H05K 5/03

(52) U.S. Cl. 174/67

(57) ABSTRACT

The present invention relates to a wall outlet cover and prong device including a cover plate of a desired shape; a cover outlet box having at least one electrical socket mounted within a wall of the outlet box; and at least one pair of electrical plug blades projecting from the cover outlet box adapted for plugging the cover and prong device into a conventional electrical wall socket.

### CROSS-REFERENCE TO RELATED APPLICATIONS

This application claims the benefit of U.S. Provisional Patent Application No. 60/826,473 filed on Sep. 11, 2006 which is incorporated herein by reference.

### BACKGROUND OF THE INVENTION

Conventional electrical outlets are made of several components, including a wall box and a receptacle which typically includes a pair of sockets. The receptacle is typically attached to the wall box which in turn is typically attached to a framing member inside the wall, and is accessible through a hole cut in the wall. A wall outlet cover plate having apertures through which the sockets protrude is installed over these components, typically with one or two screws. Electrical devices arc plugged in to the electrical outlet by inserting the plug blades of the plug at the end of an electrical wire from the electrical device in the socket. Characteristically, electrical service is provided by means of these wall outlets.

Typically, these wall outlet covers are made with drab colors. There exists a need for a way to improve the aesthetic quality of these wall covers to make them more attractive.

### SUMMARY OF THE INVENTION

According to the present invention there is disclosed a wall outlet cover and prong device comprising: a cover plate of a desired shape;

a cover outlet box having at least one electrical socket mounted within a wall of the outlet box; and at least one pair of electrical plug blades projecting from the cover outlet box adapted for plugging the cover and prong device into a conventional electrical wall socket.

Further according to the present invention the cover plate is constructed of plastic.

Still further according to the present invention the cover plate is constructed of metal.

Also according to the present invention a screw hole extends through the wall outlet cover and prong device to receive a screw for attaching the wall outlet cover and prong device to an electrical wall outlet.

Yet further according to the present invention the cover outlet box has electrical sockets in one wall of the cover outlet box into which plug blades are inserted.

Moreover according to the present invention the cover outlet box has electrical sockets within the bottom wall.

Also according to the present invention the cover outlet box has electrical sockets within a side wall.

Further according to the present invention the cover two pairs of electrical plug blades projecting from the cover outlet box adapted for plugging the cover and prong device into a conventional electrical wall socket.

### BRIEF DESCRIPTION OF THE DRAWINGS

The structure, operation, and advantages of the present invention will become further apparent upon consideration of the following description taken in conjunction wit the accompanying figures (Figs.). The figures are intended to be illustrative, not limiting.

Certain elements in some of the figures may be omitted, or illustrated not-to-scale, for illustrative clarity. The cross-sectional views may be in the form of “slices”, or “near-sighted” cross-sectional views, omitting certain background lines which would otherwise be visible in a “true” cross-sectional view, for illustrative clarity.

In the drawings accompanying the description that follows, often both reference numerals and legends (labels, text descriptions) may be used to identify elements. If legends are provided, they are intended merely as an aid to the reader, and should not in any way be interpreted as limiting.

FIG. 1 is a front view of a wall outlet cover and prong device in accordance with the present invention.

FIG. 2 is a rear view of a wall outlet cover and prong device in accordance with the present invention.

FIG. 3 is a side view of a wall outlet cover and prong device in accordance with the present invention.

FIG. 4 is a top view of a wall outlet cover and prong device in accordance with the present invention.

### DETAILED DESCRIPTION OF THE PREFERRED EMBODIMENTS

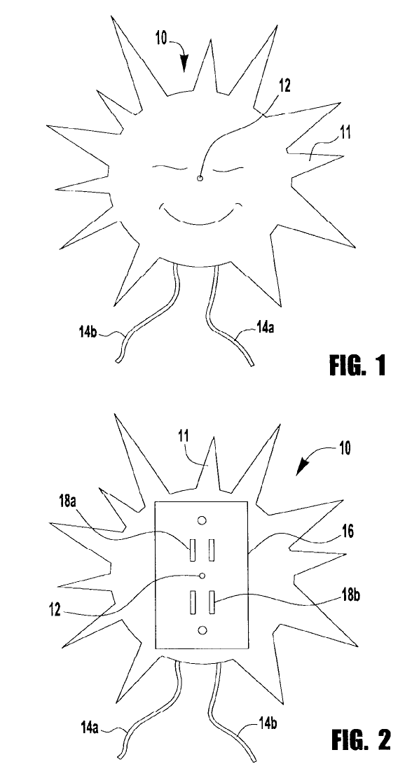

FIG. 1 illustrates the front view of the wall outlet cover and prong device 10 (called wall outlet cover device herein) according to the present invention. Wall outlet cover and prong device 10 includes a cover plate 11 that may be constructed of any desired material, such as plastic or metal. The illustrated example is just one possible shape and design. There is an enormous variety of possible shapes, designs, and colors for cover plate 11 that fall within the scope of the present invention. Wall outlet cover and prong device 10 can include a screw hole 12 to receive a conventional screw to secure the wall outlet cover and prong device 10 to the screw hole typically found in an electrical wall outlet. Electric cords 14a and 14b go to electrical devices, such as lamps, that have been plugged into wall outlet cover and prong device 10 as a source of electricity.

FIG. 2 illustrates the rear view of the wall outlet cover and prong device 10. A cover outlet box 16 complete with a pair of electrical plug blades 18a and 18b is attached by any desired means to the wall outlet cover and prong device 10 adapted for plugging the cover and prong device into a conventional electrical wall socket (not shown).

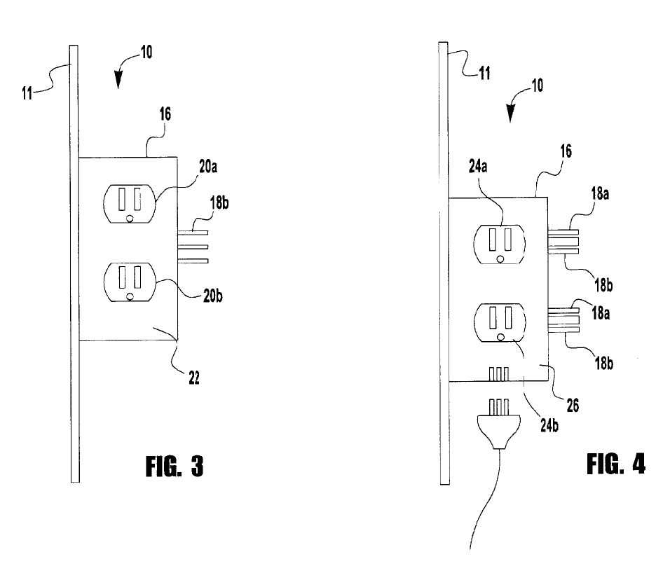

FIG. 3 illustrates the bottom view of the wall outlet cover and prong device 10. Sockets 20a and 20b are shown to be located on a bottom wall 22 of cover outlet box 16. However, it is within the scope of the present invention to place electrical sockets on any side of cover outlet box 16. The sockets 20a and 20b are connected to plug blades 18a and 18b as is conventionally known.

FIG. 4 illustrates the side view of the wall outlet cover and prong device 10. Sockets 20a and 20b schematically to be located on bottom wall 22 of cover outlet box 16.

There are several ways to use wall outlet cover and prong device 10. First, the standard outlet cover can be removed from an electrical wall socket and wall outlet cover and prong device 10 is mounted to the socket by means of electrical blades 18 (18a and 18b) and may be secured with a screw through hole 12 and into the screw hole in the wall socket. Also, wall outlet cover 10 may be used without removing the standard outlet cover by simply inserting the electrical blades 18 into the socket. Then, as shown in FIG. 4, standard plugs may be connected into the cover outlet box 16, such as through the bottom surface 22 using sockets 20 (20a and 20b).

Although the invention has been shown and described with respect to a certain preferred embodiment or embodiments, certain equivalent alterations and modifications will occur to others skilled in the art upon the reading and understanding of this specification and the annexed drawings. In particular regard to the various functions performed by the above described components (assemblies, devices, etc.) the terms (including a reference to a “means”) used to describe such components are intended to correspond, unless otherwise indicated to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more features of the other embodiments as may be desired and advantageous for any given or particular application.

1. A wall outlet cover and prong device comprising:
a cover plate of a desired shape;
a cover outlet box having at least one electrical socket mounted within a wall of the outlet box;
at least one pair of electrical plug blades projecting from the cover outlet box adapted for plugging the cover and prong device into a conventional electrical wall socket.

2. The wall outlet cover and prong device of claim 1 wherein the cover plate is constructed of plastic.

3. The wall outlet cover and prong device of claim 1 wherein the cover plate is constructed of or metal.

4. The wall outlet cover and prong device of claim 1 wherein a screw hole extends through the wall outlet cover and prong device receive a screw to attach the wall outlet cover and prong device to an electrical wall outlet.

5. The wall outlet cover and prong device of claim 1 wherein the cover outlet box has electrical sockets in one wall of the cover outlet box into which plug blades are inserted.

6. The wall outlet cover and prong device of claim 5 wherein the cover outlet box has electrical sockets within the bottom wall.

7. The wall outlet cover and prong device of claim 5 wherein
the cover outlet box has electrical sockets within a side wall.

8. The wall outlet cover and prong device of claim 1 wherein two pairs of electrical plug blades projecting from the cover outlet box adapted for plugging the cover and prong device into a conventional electrical wall socket.
